(19) United States
(12) Patent Application Publication
(10) Pub. No.: US 2013/0334168 A1
(43) Pub. Date: Dec. 19, 2013

(54) MANUFACTURING METHOD OF CIRCUIT PATTERN

(71) Applicant: HSING YA HUANG, TAOYUAN COUNTY (TW)

(72) Inventor: HSING YA HUANG, TAOYUAN COUNTY (TW)

(73) Assignee: LEADING TECH COMMUNICATIONS INC., TAIPEI CITY (TW)

(21) Appl. No.: 13/525,311

(22) Filed: Jun. 16, 2012

(51) Int. Cl. H05K 3/06; C25D 5/02

(52) U.S. Cl. 216/13; 205/125

(57) ABSTRACT

This instant disclosure provides a manufacturing method of circuit pattern. The method comprising, providing a substrate; making a metal material be attached to the substrate for obtaining a circuit subbase layer on the substrate, wherein the circuit subbase layer is a curved surface along the surface of the substrate; making an anti-coating layer on the circuit subbase layer; executing a patterned processing to the anti-coating layer to make the anti-coating layer become an antenna pattern on the substrate; etching the circuit subbase layer to make the metal material uncovered by the anti-coating layer be removed from the surface of the substrate for making the circuit subbase layer to form the antenna pattern; removing the anti-coating layer to expose the circuit subbase layer forming the circuit pattern. Therefore, the manufacturing quality of the circuit pattern can be improved and the associated cost can be saved.

### BACKGROUND

1. Technical Field

The invention relates to a circuit pattern, and in particular, to a manufacturing method of the circuit pattern.

2. Description of Related Art

FIG. 1 and FIG. 2 show cross-sectional diagrams of a traditional antenna structure 100, 100′. As shown in FIG. 1, a laser direct structuring (LDS) process is applied to a substrate 11 to make a laser activated layer 12. The substrate 11 may be a casing of a mobile device (e.g. smart phone). The laser activated layer 12 may not accord to a predetermined line width (defined by the dashed lines) because some areas are not activated by the laser, thus a jump-plated phenomenon may be occurred. Therefore, the performance of the antenna may be affected. As shown in FIG. 2, when a laser beam L is applied to a via hole of the substrate 11 for making the laser activated layer 12, some area of the via hole wall may not be totally activated due to the diameter of the via hole, the shape of the via hole or the incident angle of the laser beam L, thus the laser activated layer 12 on the top surface and the laser activated layer 12 on the bottom surface may not connect to each other through the via hole or not in a good connection status. Therefore, the performance of the antenna may also be degraded accordingly. Thus, via holes with larger diameters are used when utilizing the laser direct structuring process. The mentioned disadvantages related to the antenna or the circuit pattern made by the laser direct structuring process needs to be further improved.

### SUMMARY

An embodiment of the instant disclosure provides a manufacturing method of the circuit pattern, which can form a three-dimensional (or a curved surface) circuit pattern on the substrate. Therefore, the manufacturing quality of the circuit pattern such as antenna structure can be improved and the associated cost can be saved.

An embodiment of the instant disclosure provides a manufacturing method of the circuit pattern comprising providing a substrate; making a metal material be attached to the substrate to form a circuit subbase layer on the substrate, wherein the circuit subbase layer is a curved surface along the surface of the substrate; making an anti-coating layer on the circuit subbase layer and execute a pattern processing to the anti-coating layer, so as to make the anti-coating layer become a circuit pattern on the substrate; etching the circuit subbase layer to make the metal material uncovered by the anti-coating layer be removed from the surface of the substrate so as to make the circuit subbase layer form the circuit pattern; and removing the anti-coating layer to expose the circuit subbase layer forming the circuit pattern.

To sum up, the embodiment of the instant disclosure provides the manufacturing method of the circuit pattern, which can form a three-dimensional (or a curved surface) circuit pattern on the substrate. This method can provide sufficient binding strength between the circuit pattern and the substrate and improve the manufacturing quality of the circuit pattern as well as save the associated cost. The plastic material of the substrate which used to loading the circuit pattern isn't restrict to any specific material, which can prevent the three-dimensional pattern from color cast of the substrate and save the associated cost caused by the laser craving of the conventional method.

In order to further appreciate the characteristic and technical contents of the instant disclosure, references are hereunder made to the detailed descriptions and appended drawings in connection with the instant disclosure. However, the appended drawings are merely shown for exemplary purpose rather than being used to restrict the scope of the instant disclosure.

### BRIEF DESCRIPTION OF THE DRAWINGS

The accompanying drawings are included to provide a further understanding of the present disclosure, and are incorporated in and constitute a part of this specification. The drawings illustrate exemplary embodiments of the present disclosure and, together with the description, serve to explain the principles of the present disclosure.

FIG. 1 is a schematic diagram of the traditional antenna structure.

FIG. 2 is a schematic diagram of the traditional antenna structure.

FIG. 3 is a flow diagram of the manufacturing method of the antenna structure in the embodiment of instant disclosure.

FIG. 4A is an antenna structural sectional view of the step S300 corresponding to the embodiment of the instant disclosure.

FIG. 4B is an antenna structural sectional view of the step S310 corresponding to the embodiment of the instant disclosure.

FIG. 4C is an antenna structural sectional view of the step S330 corresponding to the embodiment of the instant disclosure.

FIG. 4D is an antenna structural sectional view of the step S350 corresponding to the embodiment of the instant disclosure.

FIG. 4E is an antenna structural sectional view of the step S370 corresponding to the embodiment of the instant disclosure.

FIG. 4F is an antenna structural sectional view of the step S390 corresponding to the embodiment of the instant disclosure.

FIG. 5 is the sub-flow diagram of the step S310 corresponding to the embodiment of instant disclosure.

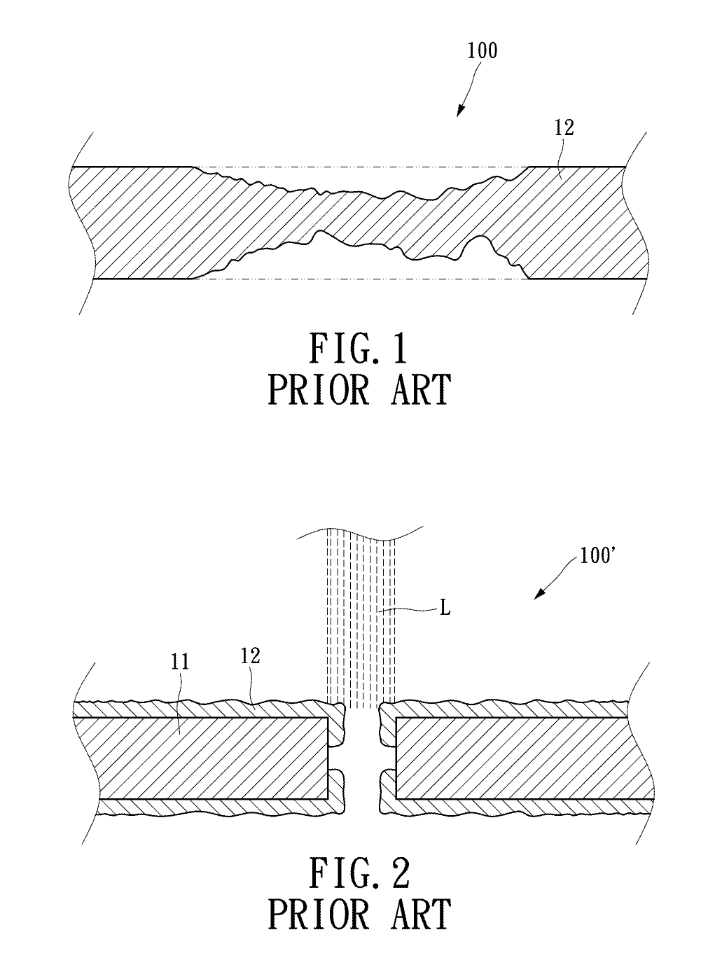

### DESCRIPTION OF THE EXEMPLARY EMBODIMENTS

An embodiment of the instant disclosure provides a manufacturing method of the circuit pattern, which can form a three-dimensional (or a curved surface) antenna structure as well as the circuit pattern for other purpose on the substrate. The above-mentioned method in the embodiment of the instant disclosure take the antenna structure manufacturing as an example, but manufacture of the antenna structure is not used to restrict the scope of this invention. In the present embodiment, the above-mention substrate might be the casing of smart mobile phone, which usually utilizes the plastic or glass substrate. However the instant disclosure is not used to restrict the kind of the substrate. In order to provide the sufficient binding strength between the antenna structure and the substrate, the manufacturing method of the antenna structure on the shell is taken as the example in this embodiment.

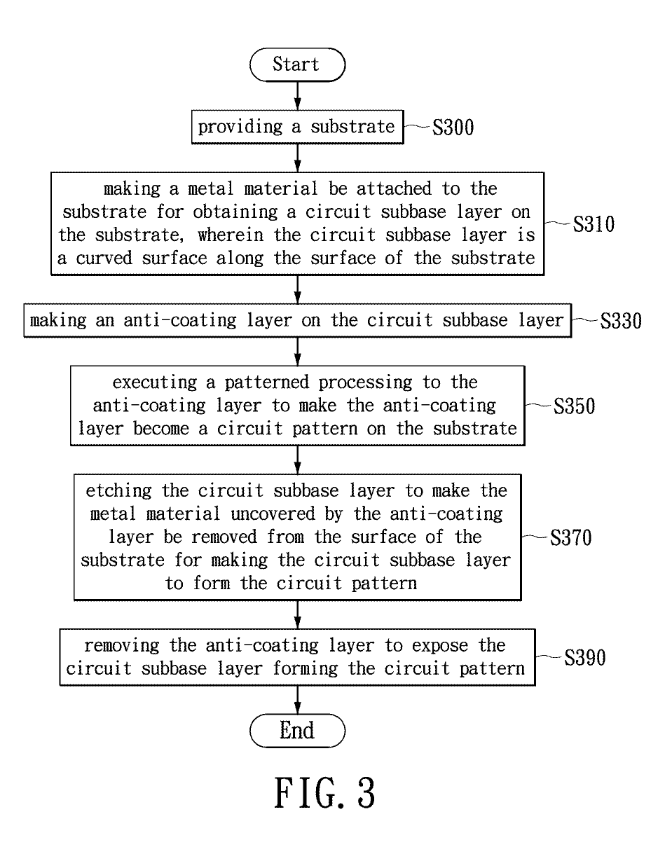

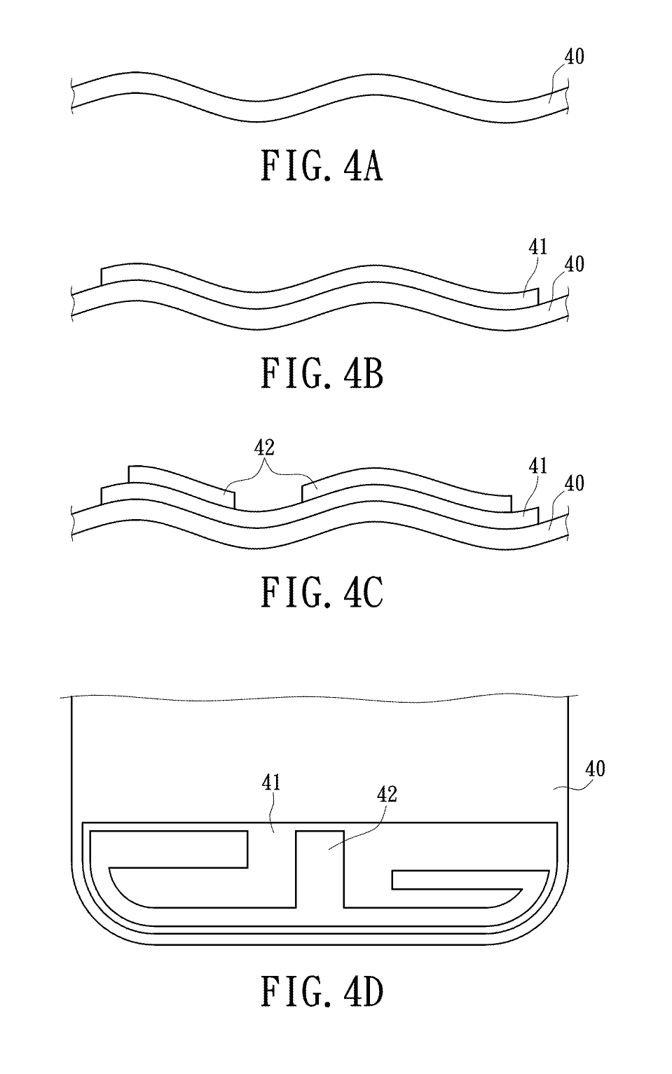

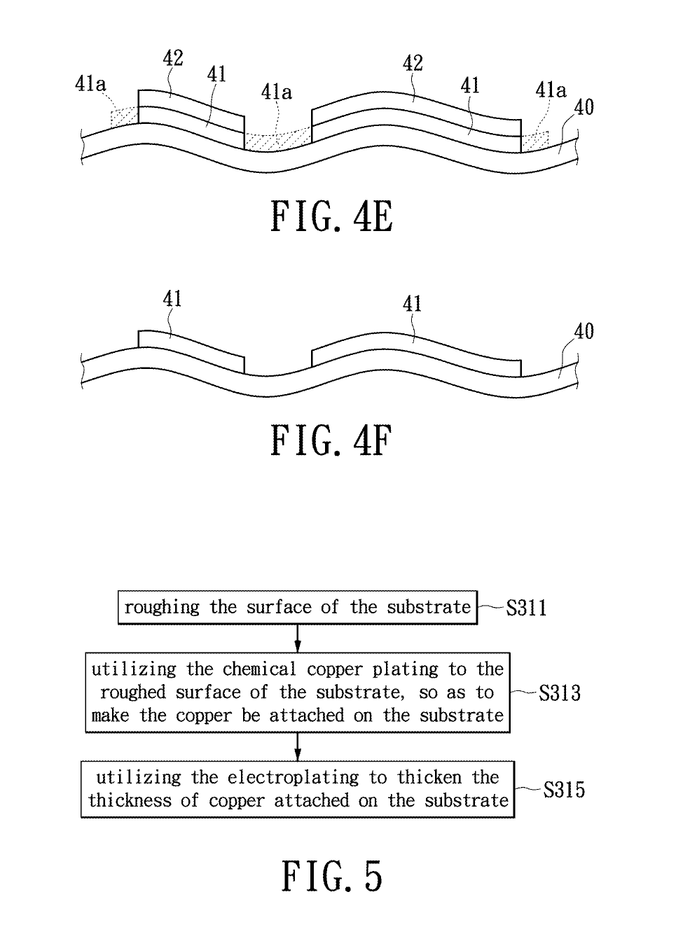

Referring to FIG. 3, FIG. 4A to FIG. 4F, FIG. 3 are the flow diagrams which describe the manufacturing method of the antenna structure (or circuit pattern) in the embodiment of instant disclosure. Besides, the FIG. 4A to FIG. 4F are the schematic diagrams corresponded to the flow process of manufacturing the antenna structure. The manufacturing method of the antenna structure comprising the following steps. First, as FIG. 4 shown, providing a substrate in the step S300. The material of the substrate can be plastic, and the method of injection molding is utilized to form the substrate, but it can't use to restrict the scope of this instant disclosure. For instance, the material of substrate might be polycarbonate, Acrylonitrile Butadiene Styrene (ABS) or the material with glass fiber. The glass substrate might also be utilizes as the substrate 40. Besides, the substrate might be a predetermined shape which is the three-dimensional patterned structure, thus the antenna structure formed on the substrate 40 might also be the three-dimensional patterned structure.

Referring to FIG. 3 and FIG. 4, in the S310 process, a metal material is attached to the substrate for obtaining a circuit subbase layer on the substrate, wherein the circuit subbase layer is a curved surface along the surface of the substrate. The method of sputtering, chemical plating (i.e., electroless plating) or electroplating is utilized to make a metal material be attached to the substrate and from a sufficient combination between circuit subbase layer 41 and substrate 40. However, the instant disclosure doesn't limit the method of making the metal material be attached to the substrate 40, for example, when the well conductivity Cu is utilized as the metal material, at least the method of sputtering, chemical plating or electroplating might be utilized to plat the copper (Cu) in the conventional method. The antenna structure could be designed to be a pattern with curved surface so as to small the size and to enhance the performance of transmitting/receiving the radio frequency signal.

That's to say, the circuit subbase layer is a curved surface along the surface of the substrate. The above-mentioned metal material for example might be Cu, Ti, Al, Mo, nichrome, indium tin oxide (ITO, 90 wt % In₂O₃ and 10 wt % SnO₂) and Au. Nevertheless, the instant disclosure isn't limited to thereto. No matter how to plat the metal material on the substrate 40, the well combination between the circuit subbase layer 41 and substrate 40 is the main purpose in this process. Thus, the antenna structure can reach its stability requirement and pass the final test after the product manufacture finished so as to enhance the high quality of manufacturing.

Moreover, in the Step S310, when there has a via hole on the substrate, the manufacturing method of instant disclosure might narrow down its size (or diameter) to about 0.1 mm to 0.3 mm. Compare to the conventional manufacturing method of the circuit pattern on the substrate, the instant disclosure can narrow down the size (or diameter) of the via hole significantly. In another word, when the via hole with the size of 0.1 mm to 0.3 mm is produced on the substrate 40, the inner side of via hole can still be covered with metal material in the S310 process. Thus, the circuit patterns on difference surfaces of the substrate 40 can connect to each other, for instance, the circuit pattern on the top surface of the substrate 40 can connect to the circuit pattern on the bottom surface of the substrate 40 by the via hole. Moreover, if the method of panel plating is utilized to thicken the thickness of the circuit subbase layer 41 in the following process, the above-mentioned via hole might be further narrow down, even might be stuffed up. (For example, it might be stuffed up with the copper which is utilizes to thicken the circuit subbase layer 41.) Thus, the via hole on the surface might be invisible for human eye, so as to improve the flatness for the visual sense of beauty. Specifically, when the substrate 40 is utilized to be the casing of the product surface, the beauty of the substrate 40 may attract the attention of customers so as to enhance the competitive of products. Furthermore, when the substrate 40 is utilized to be the casing of the product surface, the smaller via hole (or the stuffed via hole) can prevent the shell from the water vapor and foreign matter so as to enhance the protecting efficiency of the casing to the product.

Referring to the FIG. 3 and FIG. 5, FIG. 5 is the sub-flow diagram corresponding to the embodiment of instant disclosure in the step S310. Not only the sputtering and electroplating, the chemical plating may also be utilized in the process of forming a circuit subbase layer 41 on the substrate 40 as shown in FIG. 5. First, in the S311 process, the mechanical and the chemical way can be utilizes to rough the surface of the substrate 40. Then, in the step S313, the chemical copper plating is utilized on the roughed surface of the substrate 40 to make the copper be attached to the substrate. Next, in the step S315, the electroplating is utilizing to thicken the thickness of copper attached on the substrate. For example, forming a metal thickening layer on the circuit subbase layer 41, and making the total thickness of the circuit subbase layer and the metal thickening layer to reach the predetermined value. On the other hand, the electroplating is utilized to form the predetermined thickness of copper, such as 3 um (micrometer) to 16 um. However, the above-mentioned thickness can be adjusted according to the design requirement, which can't be used to restrict the scope of instant disclosure.

Referring to both of the FIG. 3 and FIG. 4C, in the step S330, make an anti-coating layer on the circuit subbase layer, wherein the photopolymerizable type or thermoset type polymer is utilized to be the anti-coating layer 42. In this embodiment, the anti-coating layer 42 may be a photopolymerization type polymer or a thermoset polymer. In this embodiment, the protection layer 41 may be accomplished by spray coating a wet film resist agent of thermal molding. Then, making thermal baking utilizing infrared ray to polymerizat the wet film resist agent for enhancing the binding strength of the resist agent. Or, utilizing a photopolymerization dry film and making lamination, exposure and development to form a corrosion-resisted dry film.

Referring to the FIG. 3 and FIG. 4D, in the step S350, execute a patterned processing to the anti-coating layer 42 to make the anti-coating layer 42 become an antenna pattern on the substrate, as the top view of the antenna structure shown in FIG. 4D, the pattern formed in the anti-coating layer 42 is pattern of the antenna structure. In the process of executing a patterned processing to the anti-coating layer, the laser might be utilized to ablating the circuit pattern surrounding of the anti-coating layer for removing the anti-coating layer except for the needed circuit pattern, so as to modify the circuit pattern. The above-mentioned laser can be the YVO₄ laser with the 1064 nm wavelength. It's worth nothing that, conventionally, the laser energy and scanning time of the laser carving technology which utilized to carve the conductive circuit or metal circuit might need to adjust so as to avoid the oversupply laser able to destroy the surface of the substrate 40 as well as the insufficient laser unable to remove the conductive circuit or metal circuit. Thus, this might increase the cost of traditional laser carving.

What is more, the energy of the (YVO₄) laser need not to adjust once it can remove the anti-coating layer 42 in this embodiment. Besides, the laser energy utilized to remove the anti-coating layer 42 is lower than the conventionally energy utilizes to remove the conductive circuit or metal circuit. Therefore, the laser energy in this embodiment is rather low which can't destroy the substrate 40 easily. That is say, in the reality process of executing a patterned processing, laser can remove the anti-coating layer 42 easily, so as to decrease the influence to the substrate 40 significantly. Nevertheless, the instant disclosure is not limited to the type of laser, a green laser with wavelength of 532 nm or other type of laser might also be utilized.

Referring to the FIG. 3 and FIG. 4E, in the step S370, etch the circuit subbase layer 41 to make the metal material uncovered by the anti-coating layer 42 be removed from the surface of the substrate 40 for making the circuit subbase layer 41 to form the antenna pattern. As shown in the FIG. 4E, the etched part 41a uncover by the anti-coating layer 42. The acid etchant can be utilized to remove the etched part 41a in the step S370. The main composition of the acid etchant usual comprising (chelating agents) nitric acid, sulfuric acid, hydrochloric acid, hydrogen peroxide, hydrogen fluoride, sodium chlorate (NaClO₃), ferric chloride, sodium persulphate (Bis-(sodiumsulfopropyl)-disulfide, SPS) and so on, but the instant disclosure isn't limited thereto.

Referring to the FIG. 3 and FIG. 4F, in the step S390, removing the anti-coating layer to expose the circuit subbase layer forming the circuit pattern. The circuit pattern of the circuit subbase layer 41 is the pattern of the anti-coating layer 42 shown in the FIG. 4D. The de-film liquid can be utilized to remove the anti-coating layer 42. For instance, the de-film liquid can be utilized to remove the dry film resist completely. The main composition of the de-film liquid can be such as the sodium carbonate (Na₂CO₃) or potassium carbonate (K₂CO₃) with the PH higher than 13. Nonetheless, the instant disclosure isn't limited to the ingredients of the de-film liquid which might be the solvent such as sodium hydroxide (NaOH) / potassium hydroxide (KOH), amine ether group, polyethylene glycol and so on.

After the step S390, form a metal thickening layer on the circuit subbase layer 41, and make the total thickness of the circuit subbase layer 41 and the metal thickening layer to reach the predetermined value. Moreover, after the step S390, it's available to form a metal protecting layer on the circuit subbase layer 41 so as to protect the antenna structure. The electroplating or elecrtolessplating can be utilized to make a metal protective layer which can be the Pd, NiPd, NiAu or the combination of Ni and anti-etching agent attached on the Ni layer. The thickness of the metal protecting layer can be over 5 um, which can be adjusted according to the demand.

The above-mentioned embodiment only takes the antenna structure of the circuit pattern as example. The manufacturing method of the circuit pattern in this embodiment of the instant disclosure might also be utilizes to manufacture the circuit of electrical circuit such as the charge coupled device (CCD), as well as to manufacture the three-dimensional patterned conductive circuit on the plastic substrate. In another word, the instant disclosure isn't limited to the purpose of the conductive circuit pattern which generated by the manufacturing method of the circuit pattern.

According to the embodiment of the instant disclosure, the above-mentioned manufacturing method of the circuit pattern can be used to form a three-dimensional (or a curved surface) circuit pattern on the plastic or glass substrate which is widely used. This can not only provide the sufficient binding strength between the circuit pattern and substrate but also improve the manufacturing quality of the circuit pattern and save the associated cost. The plastic material of the substrate which used to loading the circuit pattern isn't restrict to any specific material, which can not only prevent the three-dimensional patterned from color cast of the substrate but also save the associated cost caused by the laser craving of the conventional method. Moreover, when there has a via hole (or via holes) on the substrate, the via hole might be narrow down, even be stuffed up, so as to improve the flatness. Besides, the smaller via hole (or the stuffed via hole) can prevent the products from the influence of the water vapor and foreign matter.

While the embodiments of the instant disclosure have been set forth for the purpose of disclosure, without any invention to limit the scope of the present disclosure thereto.

What is claimed is:

1. A manufacturing method of the circuit pattern, comprising:
providing a substrate;
making a metal material be attached to the substrate for obtaining a circuit subbase layer on the substrate, wherein the circuit subbase layer is a curved surface along the surface of the substrate;
making an anti-coating layer on the circuit subbase layer;
executing a patterned processing to the anti-coating layer to make the anti-coating layer become a circuit pattern on the substrate;
etching the circuit subbase layer to make the metal material uncovered by the anti-coating layer be removed from the surface of the substrate for making the circuit subbase layer to form the circuit pattern; and
removing the anti-coating layer to expose the circuit subbase layer forming the circuit pattern.

2. A manufacturing method of the circuit pattern of claim 1, wherein the process between the metal material attachment and the anti-coating layer formation further comprising:
forming a metal thickening layer on the circuit subbase layer, and making the total thickness of the circuit subbase layer and the metal thickening layer to reach a predetermined value.

3. A manufacturing method of the circuit pattern of claim 2, wherein the method of sputtering, chemical plating or electroplating is utilized to make a metal material be attached to the substrate.

4. A manufacturing method of the circuit pattern of claim 2, wherein the metal material comprising Cu, Ti, Al, Mo, nichrome, indium tin oxide(ITO, 90 wt% In₂O₃ and 10 wt % SnO₂) and Au.

5. A manufacturing method of the circuit pattern of claim 1, wherein the the anti-coating layer is photopolymerizable type or thermoset type polymer.

6. A manufacturing method of the circuit pattern of claim 1, wherein the process after removing the anti-coating layer further comprising:
forming a metal thickening layer on the circuit subbase layer.

7. A manufacturing method of the circuit pattern of claim 1, wherein the process of executing a patterned processing to the anti-coating layer comprise the usage of laser to ablating the circuit pattern surrounding of the anti-coating layer for modifying the circuit pattern.

8. A manufacturing method of the circuit pattern of claim 1, wherein the process after removing the anti-coating further comprising:
forming a metal protective layer on the circuit subbase layer which forms the circuit pattern.

9. A manufacturing method of the circuit pattern of claim 1,
wherein when the electroplating process is utilized to the process of making a metal material be attached to substrate for obtaining a circuit subbase layer on the substrate, the diameter of at least one of the via hole on the substrate is between 0.1 mm and 0.3 mm.

10. A manufacturing method of the circuit pattern of claim 1,
wherein the process of making a metal material be attached to substrate comprising:
roughening the surface of the substrate;
utilizing the chemical plating to rough the surface of the substrate, so as to make the copper be attached on the substrate; and
utilizing the electroplating to thicken the thickness of copper attached on the substrate.
